(19) United States
(12) Patent Application Publication
(10) Pub. No.: US 2010/0236618 A1
(43) Pub. Date: Sep. 23, 2010

(54) METHOD FOR MANUFACTURING A PHOTOVOLTAIC CELL AND A PHOTOVOLTAIC CELL OBTAINED WITH SUCH A METHOD

(75) Inventor: Martin Dinant Bijker, Helmond (NL)

Correspondence Address: PILLSBURY WINTHROP SHAW PITTMAN, LLP, P.O. BOX 10500, MCLEAN, VA, 22102, US

(73) Assignee: OTB Solar B.V., EB Eindhoven (NL)

(21) Appl. No.: 12/682,439

(22) PCT Filed: Oct. 13, 2008
(86) PCT No.: PCT/NL08/50645

§ 371 Date: Jun. 9, 2010

(30) Foreign Application Priority Data
Oct. 12, 2007 (NL) 1034513

(51) Int. Cl. H01L 31/0232; H01L 31/18

(52) U.S. Cl. 136/256; 438/72; 257/E21.295; 257/E31.127

(57) ABSTRACT

A method for manufacturing a photovoltaic cell, such as a solar cell is disclosed. The method includes: providing a silicon substrate; applying to a side of the silicon substrate, a first layer of a metal with a relatively high optical reflectance, such as a layer of silver; applying to the first layer, a second layer of a metal with a relatively high electrical conductivity coefficient, such as a layer of aluminum or an Al alloy; and then firing the substrate having the first and second layers in order to obtain an alloy of the metals of the first and second layers and the silicon, wherein the alloy formed comprises a maximum amount of metal dissolved in the silicon in amounts up to the eutectic point of the alloy. In one implementation, the alloy is substantially an n-type Si—Al—Ag alloy. Thus, an improved Back Surface Field is formed in the substrate. The invention further relates to a photo voltaic cell obtained with the aid of such method.

The invention relates to a method for manufacturing a photovoltaic cell, such as a solar cell.

Such methods are known from practice. With a first known method, a layer of aluminum is applied to a silicon substrate. Such a layer is important for the optically reflective and electrically conductive properties of the substrate. In a part of the substrate adjoining the applied layer of aluminum, an alloy is formed between the aluminum and the silicon. This Al—Si alloy has a negative charge with respect to the p-type silicon. In this manner, an n-p junction, a so-called “Back Surface Field, is created on a rear side of the substrate, effecting the electrons which diffuse to the rear side of the substrate to be diverted. This is favourable to the efficiency of the photovoltaic cell. Upon formation of the alloy between the aluminum and the silicon of the substrate, at most approximately 3% by weight of aluminum can dissolve in the silicon. In order to obtain a higher n-charge in the Back Surface Field, according to another known method, instead of a layer of aluminum, also a layer of an Al—Ag alloy is applied, so that the Back Surface Field is formed by an Al—Ag—Si alloy. However, a drawback of such a method is that an Al—Ag alloy is relatively expensive with respect to merely an aluminum layer. Further, only a part of the Al—Ag alloy is used during the formation of the alloy with silicon, therefore also only a part of the silver from the alloy. As a result, the silver in the Al—Ag alloy on the side remote from the substrate remains unused, which is undesired from a point of view of costs.

It is therefore an object of the invention to provide a method for manufacturing a photovoltaic cell without the above-mentioned drawbacks. More particularly, it is an object of the invention to provide a method for manufacturing a photovoltaic cell which has an improved Back Surface Field and at the same time can be manufactured relatively inexpensively.

In order to achieve this object, the method of the type mentioned in the introductory portion is characterized in that the method comprises the following steps:
providing a silicon substrate;
applying to a rearmost side a first layer of a metal with a relatively high optical reflectance, preferably a layer of silver;
applying to the first layer a following layer of a metal with a relatively high electrical conductivity coefficient, preferably a layer of aluminum or an Al alloy;
then firing the substrate in order to obtain an alloy of the metals and the silicon, wherein the formed alloy comprises, at most, an amount of metal, preferably aluminum and silver, in silicon in amounts up to the eutectic point of the alloy, which alloy is substantially an n-type Si—Al—Ag alloy whereby a better Back Surface Field is obtained.

By manufacturing a photovoltaic cell with the method according to the invention, a maximum percentage of up to, at most, approximately 10 mol % of metal is diffused into the silicon. This is because when the eutectic point of the alloy is reached, a maximum amount of Al—Ag alloy has dissolved into the silicon lattice, and no more metal can be dissolved into the silicon. The aluminum diffuses up to approximately 3 micrometers into the opposite silicon and the silver applied between the aluminum and the silicon diffuses together with the aluminum. Therefore, an alloy of aluminum, silver and silicon is formed with a relatively high n-charge, thereby creating an efficient Back Surface Field. As the silver is located between the aluminum and the silicon, the silver is used efficiently during formation of the alloy with the silicon and no unused silver remains behind in the bulk. This is favourable to the costs of manufacturing the photovoltaic cell with the method according to the invention. An additional advantage is that the silver involves substantially a full surface coating so that a maximum percentage of % by weight of silver ends up in the alloy, so that a maximum n-charge is obtained, resulting in a Back Surface Field that diverts electrons diffusing towards the rear side of the photovoltaic cell to a maximum. The full surface coating of silver also provides a higher degree of reflection for incident light on the photovoltaic cell. Owing to these properties, the efficiency of the photovoltaic cell is enhanced.

In a further elaboration of the invention, the first metal layer is provided in a thin layer, wherein the thickness of the layer is substantially in the range of 10 nanometers −1 micrometer. By applying only a thin layer, the amount of silver is limited to the amount actually required that obtains a maximum result as described hereinabove, while simultaneously the manufacturing costs are reduced.

It is favourable if, according to a further embodiment of the invention, the first metal layer is applied with the aid of a deposition process, preferably sputtering. Applying through sputtering is characterized by a high application speed. This contributes to a relatively rapid cycle time of the manufacturing process of the photovoltaic cell.

According to a further embodiment of the invention, the following metal layer is applied in a thickness substantially in the range of 10 micrometers −25 micrometers. Preferably, according to a further elaboration of the invention, this following metal layer is applied with the aid of a printing process, preferably screen printing. The advantage of screen printing the following metal layer, the aluminum layer, is that the layer can be pre-patterned. As a result, when applying the aluminum layer, for instance the busbars on the substrate can be taken into account.

The invention further relates to a photovoltaic cell obtained with the aid of the above-described method. Such a photovoltaic cell offers the same effects and advantages as those which are mentioned in the description of the method.

Further elaborations of the invention are described in the subclaims and will be elucidated in the following with reference to the drawings. In the drawings:

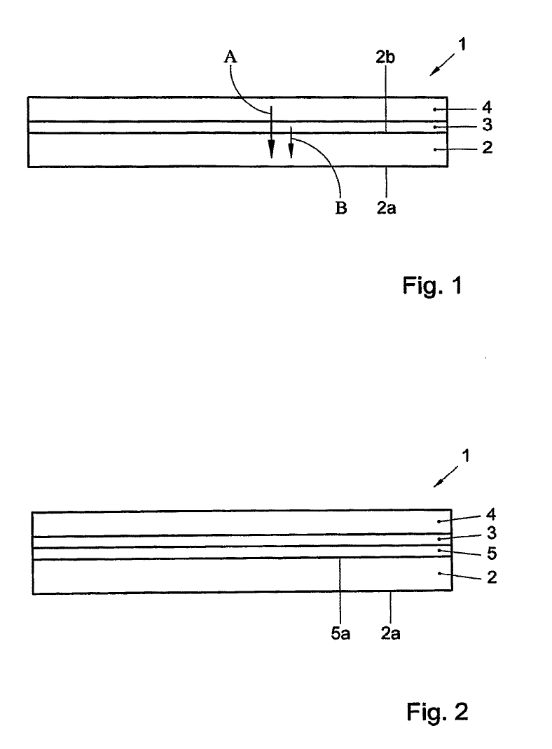

FIG. 1 shows a schematic cross section of a substrate provided with a silver and aluminum layer before the firing step of the method according to the invention; and

FIG. 2 shows a schematic cross section of a substrate provided with a silver and aluminum layer after the firing step of the method according to the invention.

Identical parts are indicated in the different Figures with identical reference numerals.

In FIG. 1, a schematic cross section is shown of a substrate 2 provided with two metal layers 3, 4. In order to manufacture a photovoltaic cell 1 according to the method of the invention, a substrate 2 is provided. On a rearmost side 2b of the substrate 2, a first metal layer with a high optical reflectance is provided, in this exemplary embodiment a silver layer 3. This silver layer 3 is applied with the aid of sputtering, which provides a high-speed application of the silver layer 3.

Then, to the silver layer 3 is applied a following metal layer 4 with a high electrical conductivity coefficient. In this exemplary embodiment, this metal layer is a layer of aluminum 4. This layer of aluminum 4 preferably has a thickness in the range of 10 micrometers and 25 micrometers. Such a thickness of the layer of aluminum effects that the solar cell can process approximately 5 amperes of energy.

To then obtain a solar cell which is provided with an efficient Back Surface Field, hence with a relatively high n-charge, the substrate with the silver layer and the aluminum layer present thereon is fired according to the method according to the invention. As a result, the aluminum layer 4 and the silver layer 3 form an alloy with the rearmost side 2b of the silicon substrate 2. Forming the alloy takes place by firing the whole according to a standard generally known firing profile. Through firing, both the aluminum atoms (see arrow A in FIG. 1) and the silver atoms (see arrow B in FIG. 1) diffuse up to approximately 3 micrometers into the silicon. As a large stream of aluminum atoms diffuses to the silicon, the silver atoms will substantially diffuse together with the aluminum atoms into the silicon so that an alloy of aluminum with silver and silicon is formed on a side 2b of the substrate proximal to the metal layers 3, 4. By utilizing the method according to the invention, the Al—Ag—Si alloy contains a maximum amount of aluminum and silver in the silicon belonging to the eutectic point of the alloy. When reaching the eutectic point, the alloying process stops automatically, since no more metal atoms can be taken up into the silicon lattice.

The composition of the solar cell 1 after the firing step is schematically represented in FIG. 2. The formed Al—Ag—Si alloy 5 is an n-type alloy and has a relatively high n-charge due to the presence of silver atoms in the alloy. Due to this n-charge in this rearmost part 2b of the substrate 2, a solar cell 1 is obtained with an efficient Back Surface Field 5. In use, the electrons diffusing to the rear side 2b of the solar cell 1 are diverted to the side 5a of the Back Surface Field 5 proximal to the silicon, so that these electrons re-enter the silicon. As a result, the efficiency of the solar cell 1 is enhanced. Further, the silver full surface coating on the rear side 2b of the substrate 2 provides for a good optical reflection of light falling thereon and heat falling thereon, which enter the silicon substrate of the solar cell 1 via the foremost side 2a. As a result, the incident light is used more effectively, which is also favourable to the operation of the solar cell 1. The aluminum layer 4 at the extreme rear side of the solar cell 1 effects a good discharge of the generated electric power.

It will be clear that the invention is not limited to the described exemplary embodiment but that various modifications are possible within the framework of the invention as defined by the claims. Instead of a silver layer as intermediate layer, also a layer of a different metal can be provided. The prerequisites are that the metal can be sputtered, in any case can be applied at a high application speed, that is has good reflective properties, can alloy with aluminum and with silicon and in alloyed condition provides an n-type alloy. Also, in another exemplary embodiment, the first metal layer can be applied through a different deposition technique. It is further clear to the skilled person that for the second metal layer, also other metals with properties similar to those of aluminum can be used, and also a different process can be used for applying the second metal layer.

1. A method for manufacturing a photovoltaic cell comprising:
providing a silicon substrate;
applying to a side of the silicon substrate, a first layer of a metal with a relatively high optical reflectance;
applying to the first layer, a second layer of a metal with a relatively high electrical conductivity coefficient; and
then firing the silicon substrate having the first and second layers in order to form a Back Surface Field in the substrate having a relatively high n-charge, the Back Surface including an n-type alloy of the metals of the first and second layers and the silicon,
wherein the n-type alloy comprises a maximum amount of metal, dissolved in the silicon in amounts up to the eutectic point of the alloy.

2. The method according to claim 1, wherein the first metal layer is applied in a thin layer having a thickness substantially in the range of 10 nanometers-1 micrometer.

3. The method according to claim 1, wherein the first metal layer is applied with a deposition process.

4. The method according to clam 1, wherein the second metal layer is applied in a thickness substantially in the range of 10 micrometers-25 micrometers.

5. The method according to claim 1, wherein the second metal layer is applied with a printing process.

6. A photovoltaic cell formed by the method according to claim 1.

7. The method according to claim 1, wherein the photovoltaic cell is a solar cell.

8. The method according to claim 1, wherein the first layer is silver.

9. The method according to claim 1, wherein the second layer is a layer of aluminum or an Al alloy.

10. The method according to claim 1, wherein the n-type alloy is an n-type Si—Al—Ag alloy

11. The method according to claim 2, wherein the deposition process is sputtering.

12. The method according to claim 5, wherein the printing process is screen printing.

13. The method according to claim 1, wherein approximately 10 mol % of metal is diffused into the silicon.

14. The method according to claim 1, wherein the first layer is silver, and the second layer is a layer of aluminum or an Al alloy.

15. The method according to claim 14, wherein the aluminum and silver atoms diffuse approximately 3 micrometers into the silicon.

16. The method according to claim 14, wherein a maximum amount of aluminum and silver are dissolved in the silicon corresponding to the eutectic point of the alloy.

17. The method according to claim 1, wherein once the eutectic point of the alloy is reached no more metal can be dissolved in the silicon.

18. The method according to claim 1, wherein the first layer of a metal is fully coated on the side of the silicon substrate.

19. A photovoltaic cell comprising:
a silicon substrate including a Back Surface Field formed in a surface region thereof having a relatively high n-charge;
a first layer of a metal with a relatively high optical reflectance formed on the surface of the substrate; and
a second layer of a metal with a relatively high electrical conductivity coefficient formed on the first layer,
wherein the Back Surface. Field includes an n-type alloy of the metals of the first and second layers and the silicon having a maximum amount of metal dissolved in the silicon up to the eutectic point of the alloy.

20. The photovoltaic cell according to claim 19, wherein the first layer is silver, and the second layer is a layer of aluminum or an Al alloy.
